(19) United States
(12) Patent Application Publication
(10) Pub. No.: US 2026/0118112 A1
(43) Pub. Date: Apr. 30, 2026

(54) SUBSTRATE PROCESSING APPARATUS AND MEASURING METHOD

(71) Applicant: Tokyo Electron Limited, Tokyo (JP)

(72) Inventors: Yasuaki NODA, Kumamoto (JP); Kazuya HISANO, Kumamoto (JP); Norihisa KOGA, Kumamoto (JP); Wataru IIHOSHI, Kumamoto (JP); Kousuke NAKAYAMA, Hokkaido (JP)

(21) Appl. No.: 19/365,666

(22) Filed: Oct. 22, 2025

(30) Foreign Application Priority Data
Oct. 29, 2024 (JP) 2024-189545

(51) Int. Cl. G01B 11/06; G03F 7/00; G03F 7/16; H01L 21/66; H01L 21/67

(52) U.S. Cl. CPC G01B 11/0616; G03F 7/16; G03F 7/70716; G03F 7/7085; H10P 72/0422; H10P 74/203

(57) ABSTRACT

A substrate processing apparatus includes a transfer device, a measurement device, and a control unit. The transfer device includes a transfer arm configured to hold and transfer a substrate. The measurement device measures a thickness of a film positioned on a surface of the substrate. The measurement device includes a housing having an opening that allows the substrate held by the transfer arm to pass therethrough, and a film thickness meter provided in the housing to measure the thickness of the film of the substrate. The control unit controls the transfer device to move the transfer arm such that the substrate passes through the opening of the housing while being held by the transfer arm, and measures the thickness of the film using the film thickness meter.

### CROSS-REFERENCE TO RELATED APPLICATIONS

This application is based on and claims priority from Japanese Patent Application No. 2024-189545, filed on Oct. 29, 2024, with the Japan Patent Office, the disclosure of which is incorporated herein in its entirety by reference.

### TECHNICAL FIELD

The present disclosure relates to a substrate processing apparatus and a measuring method.

### BACKGROUND

Japanese Patent No. 7282171 discloses a technique in which a substrate is transferred into a cassette chamber using a transfer device, the substrate is fixed on a fixing stage provided in the cassette chamber, and then the thickness of a film positioned on the surface of the substrate is measured by moving a film thickness meter above the substrate.

### SUMMARY

A substrate processing apparatus according to an aspect of the present disclosure includes a transfer device, a measurement device, and a control unit. The transfer device has a transfer arm configured to hold and transfer a substrate. The measurement device is configured to measure the thickness of a film positioned on a surface of the substrate. The measurement device includes a housing having an opening configured to allow a substrate held by the transfer arm to pass therethrough, and a film thickness meter provided in the housing and configured to measure the thickness of the film of the substrate. The control unit is configured to control the transfer device to move the transfer arm such that the substrate held by the transfer arm passes through the opening of the housing, and to control the film thickness meter to measure the thickness of the film.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view schematically illustrating an outline of a configuration of a substrate processing system according to an embodiment.

FIG. 2 is a front view schematically illustrating an outline of a configuration of a substrate processing system according to an embodiment.

FIG. 3 is a schematic front view of a measurement device according to an embodiment.

FIG. 4 is a schematic side view of a measurement device according to an embodiment.

FIG. 5 is a partial cross-sectional view taken along line V-V of FIG. 3.

FIG. 6 is a view illustrating an example of positions for measuring a thickness of a film.

FIG. 7 is a view illustrating a variation in measurement result of an optical meter caused by an inclination of a transfer arm.

FIG. 8 is a schematic bottom view of a measurement device according to an embodiment.

FIG. 9 is a schematic view illustrating an example of a state in which a housing of a measurement device is placed on a cassette stage.

FIG. 10 is a flowchart illustrating an example of a procedure of a measurement process executed by a substrate processing system according to an embodiment.

FIG. 11 is a flowchart illustrating another example of a procedure of a measurement process executed by a substrate processing system according to an embodiment.

FIG. 12 is a flowchart illustrating yet another example of a procedure of a measurement process executed by a substrate processing system according to an embodiment.

FIG. 13 is a schematic front view of a measurement device according to Modification 1 of the embodiment.

FIG. 14 is a view illustrating an example of positions for measuring a thickness of a film.

FIG. 15 is a plan view schematically illustrating an outline of a configuration of a substrate processing system according to Modification 2 of the embodiment.

FIG. 16 is a front view schematically illustrating an outline of a configuration of a substrate processing system according to the second modification of the embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing a bonding apparatus, a substrate processing apparatus, and a measuring method according to the present disclosure will be described in detail with reference to the drawings. It is to be noted that the present disclosure is not limited to these embodiments. Respective embodiments may be appropriately combined as long as the processing contents do not contradict each other. In each of the following embodiments, the same components are denoted by the same reference numerals, and duplicate descriptions are omitted.

In the embodiments described below, expressions such as “constant,” “orthogonal,” “vertical,” or “parallel” may be used. However, these expressions do not necessarily require strict constancy, orthogonality, verticality, or parallelism. In other words, the above expressions are intended to allow for errors and tolerances, for example, in manufacturing accuracy or installation accuracy.

In addition, in the drawings referred to below, in order to facilitate understanding of the description, an orthogonal coordinate system may be represented in which an X-axis direction, a Y-axis direction, and a Z-axis direction orthogonal to each other are defined, and the positive Z-axis direction is set as the vertically upward direction. Furthermore, a rotational direction about a vertical axis as a center of rotation may be referred to as a θ-direction.

### Embodiment

### <Substrate Processing System>

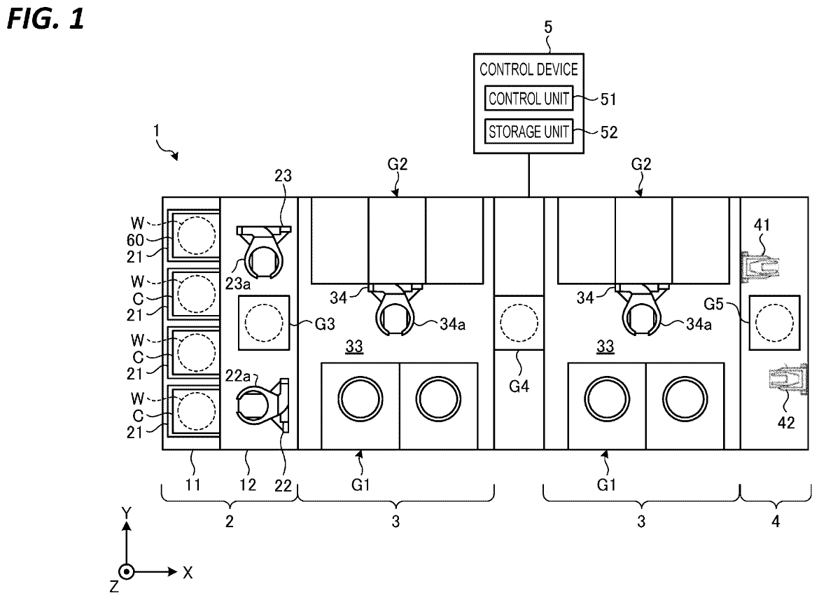

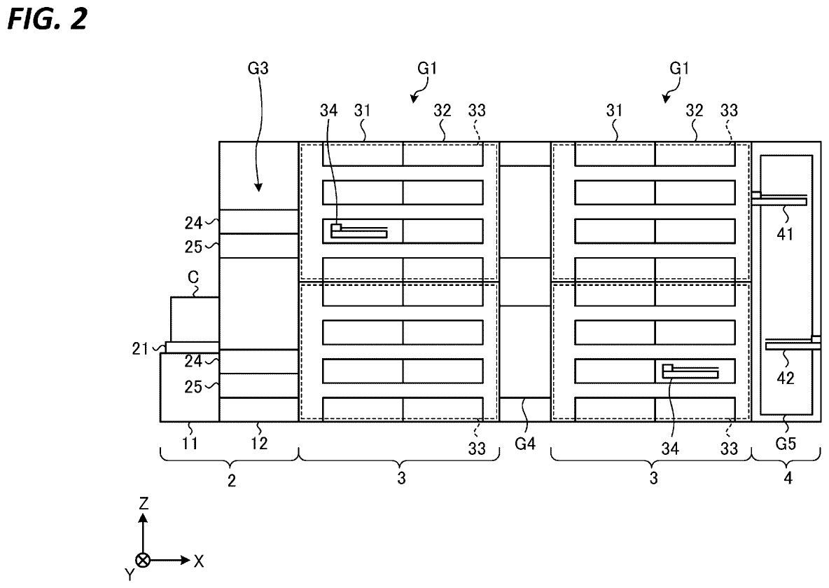

First, the configuration of a substrate processing system 1 (an example of a substrate processing apparatus) according to the present embodiment will be described. FIG. 1 is a plan view schematically illustrating an outline of the configuration of the substrate processing system 1 according to the embodiment. FIG. 2 is a front view schematically illustrating an outline of the configuration of the substrate processing system 1 according to the embodiment. In the present embodiment, descriptions will be made on a case where the substrate processing system 1 is a photolithography processing system that performs a resist film forming process and a developing process on a wafer W, as an example.

As illustrated in FIG. 1, the substrate processing system 1 includes a cassette station 2 configured such that cassettes C, each accommodating a plurality of wafers W (an example of substrates), are carried into or carried out from the cassette station, and a processing station 3 provided with multiple kinds of processing apparatuses that perform predetermined processes on the wafers W. In addition, the substrate processing system 1 has a configuration in which the cassette station 2, the processing station 3, and an interface station 4, which transfers wafers W among the cassette station 2, the processing station 3, and an exposure apparatus (not illustrated) adjacent to the side opposite to the processing station 3, are integrally connected. As illustrated in FIG. 1, two processing stations 3 are provided between the cassette station 2 and the interface station 4; however, one processing station may be provided, or three or more processing stations may be provided.

The cassette station 2 includes a cassette mounting section 11 and a transfer section 12. The cassette mounting section 11 is provided with a plurality of cassette stages 21. A cassette C, which accommodates a plurality of wafers W in a horizontal state, is disposed on each cassette stage 21. In addition, a measurement apparatus 60 is disposed on a cassette stage 21. The measurement device 60 measures the thickness of a resist film (as an example of a film) positioned on a surface of a wafer W. The configuration of the measurement device 60 will be described later.

The transfer section 12 is disposed between the cassette mounting section 11 and the processing station 3, and includes transfer devices 22 and 23 therein. The transfer devices 22 and 23 respectively have transfer arms 22a and 23a configured to hold and transfer wafers W. In the cassette station 2, wafers W are transferred between the cassettes C or the measurement device 60 placed on the cassette stages 21 and the processing station 3 by the transfer device 22 or the transfer device 23. For this purpose, the transfer devices 22 and 23 may each include, as necessary, a drive mechanism having movement paths in directions such as a horizontal direction (e.g., X direction and Y direction), a vertical direction (e.g., Z direction), and rotational direction about a vertical axis (e.g., θ-direction), and may each include a drive mechanism having movement paths in all directions. At least one of the transfer devices 22 and 23 may transfer wafers W to and from the measurement device 60 or the cassettes C and may also perform a wafer W transfer operation to and from the processing station 3 using the transfer arm 22a or 23a. The wafer W transfer operation to and from the processing station 3 refers, for example, to transferring wafers to and from the third block G3 that is provided in the transfer section 12 of the processing station 3 and includes a transfer device accessible by a transfer device 34 in the processing station 3 described later. The third block G3 is provided in the transfer section 12 of the processing station 3. A plurality of transfer devices 24 and a plurality of notch adjustment devices 25 are disposed in the third block G3.

Each notch adjustment device 25 includes a substrate rotation table on which a wafer W is placed, and an optical sensor that optically detects a notch position of the wafer W. The notch adjustment device 25 rotates the wafer W using the substrate rotation table, detects the notch position of the wafer W using the optical sensor, and performs a notch position adjustment process that adjusts the detected notch position to a predetermined position.

An inspection device (not illustrated) for inspecting the wafer W may be provided at a position accessible by one of the transfer devices 22 and 23.

The processing station 3 is provided with a plurality of blocks such as a first block G1 and a second block G2. For example, the first block G1 is provided on the front side of the processing station 3 (e.g., the negative Y-axis direction side in FIG. 1), and the second block G2 is provided on the rear side of the processing station 3 (e.g., the positive Y-axis direction side in FIG. 1). A fourth block G4 is provided on the interface station 4 side (e.g., the positive X-axis direction side in FIG. 1) of the processing station 3, or at a connection portion with another adjacent processing station 3. The fourth block G4 may include a plurality of transfer devices arranged in a vertical direction. In addition, the third block G3 may be provided in the processing station 3.

A plurality of processing apparatuses, such as a patterning film forming apparatus 31 and a developing apparatus 32, are disposed in the first block G1. As for the patterning film forming apparatus 31, for example, in addition to a resist film forming apparatus, an antireflection film (e.g., an underlayer film) forming apparatus may be included. For example, the plurality of processing apparatuses are arranged side by side in a horizontal direction. Furthermore, as illustrated in FIG. 2, a plurality of layers including the patterning film forming apparatus 31 and the developing apparatus 32 are stacked in a vertical direction. The number, arrangement, and types of these processing apparatuses may be arbitrarily selected.

In the patterning film forming apparatus 31 and the developing apparatus 32, for example, a predetermined processing liquid may be supplied onto a wafer W, or a predetermined gas may be supplied. The patterning film forming apparatus 31 performs a resist film forming process of forming a resist film on a wafer W by supplying a processing liquid for resist film formation onto the wafer W while rotating the wafer W at a predetermined rotation speed. The resist film is a film used as a mask when forming a pattern of an underlying film. In addition, the patterning film forming apparatus 31 performs an antireflection film forming process of forming an antireflection film on a wafer W by supplying a processing liquid for antireflection film formation onto the wafer W while rotating the wafer W at a predetermined rotation speed. The antireflection film is a film for efficiently performing a light irradiation process, such as an exposure process, as an example. Further, the developing apparatus 32 performs a developing process of removing a portion of the exposed resist film to form an uneven shape serving as a mask by supplying a processing liquid for development onto a wafer W while rotating the wafer W at a predetermined rotation speed. The developing apparatus 32 may also perform a resist film removal process of removing the entire resist film by supplying a processing liquid for removal onto a wafer W while rotating the wafer W at a predetermined rotation speed.

For example, in the second block G2, heat treatment apparatuses (not illustrated) for performing heat treatment such as heating or cooling of a wafer W are arranged in the vertical direction and the horizontal direction. In addition, the second block G2 is also provided, although not illustrated, with hydrophobic treatment apparatuses that each perform hydrophobic treatment to improve adhesion between a resist liquid and a wafer W, and peripheral exposure apparatuses that each expose a peripheral portion of a wafer W. These apparatuses are arranged in the vertical direction (e.g., the Z-axis direction in FIG. 2) and the horizontal direction. The number and arrangement of heat treatment apparatuses, hydrophobic treatment apparatuses, and peripheral exposure apparatuses may be arbitrarily selected.

As illustrated in FIG. 1, in a region sandwiched between the first block G1 and the second block G2 in plan view, a wafer transfer region 33 is formed. A transfer device 34 is disposed in the wafer transfer region 33.

The transfer device 34 has a transfer arm 34a that is movable, for example, in the Y direction, a front-rear direction, a θ-direction, and a vertical direction. The transfer device 34 may move within the wafer transfer region 33 to transfer wafers W to predetermined apparatuses in the surrounding first block G1, the second block G2, and the third block G3 and the fourth block G4. When a plurality of processing stations 3 are provided as illustrated in FIG. 1, the transfer device 34 provided in the processing station 3 located on the interface station 4 side may transfer wafers W not only to predetermined apparatuses in the first, second, and fourth blocks G1, G2, and G4 but also to predetermined apparatuses in a fifth block G5, which will be described later.

As illustrated in FIG. 2, a plurality of transfer devices 34 are arranged vertically. A single transfer device 34 may transfer wafers W to predetermined apparatuses located at the heights of multiple upper layers (e.g., four layers) among the plurality of vertically stacked layers. For other multiple lower layers located below those layers (e.g., four layers), another transfer device 34 may transfer wafers W to the predetermined apparatuses. A plurality of wafer transfer regions 33 are provided so as to enable such transfer of wafers W. The number of transfer devices 34 and the number of layers corresponding to one transfer device 34, for example, providing one transfer device 34 for each layer, may be arbitrarily selected.

A shuttle transfer device (not illustrated) may also be provided in the wafer transfer region 33 or in the first block G1 or the second block G2. The shuttle transfer device transfers wafers W linearly between a space adjacent to one side of the processing station 3 and another space adjacent to the opposite side.

The interface station 4 is provided with a fifth block G5 including a plurality of transfer devices, and transfer devices 41 and 42. The interface station 4 transfers wafers W between the fifth block G5, in which wafers W are transferred by the transfer device 34, and an exposure apparatus, using the transfer device 41 or the transfer device 42. For this purpose, the transfer devices 41 and 42 may each be provided, as necessary, with a drive mechanism having movement paths in directions such as a horizontal direction (e.g., X direction, Y direction), a vertical direction (e.g., Z direction), and about a vertical axis (e.g., θ-direction), and may each also be provided with a drive mechanism having movement paths in all directions. At least one of the transfer devices 41 and 42 may support a wafer W and transfer the wafer W between a transfer device in the fifth block G5 and the exposure apparatus.

A cleaning apparatus for cleaning the surface of a wafer W, or the above-described peripheral exposure apparatus, may also be provided in the interface station 4 at a position accessible by one of the transfer devices 41 and 42.

The inspection apparatus may be provided in the cassette station 2 as described above; however, the inspection apparatus may also be provided in the processing station 3 or in the interface station 4 at a position accessible by one of the transfer arms provided therein (e.g., 34, 41, or 42 in FIG. 1 or FIG. 2).

As illustrated in FIG. 1, the substrate processing system 1 includes a control device 5. The control device 5 is, for example, a computer, and includes a control unit 51 and a storage unit 52. In the storage unit 52, programs for controlling various kinds of processes executed in the substrate processing system 1 are stored. The control unit 51 is, for example, a central processing unit (CPU), and controls the operation of the substrate processing system 1 by reading out and executing the programs stored in the storage unit 52.

The programs may be recorded on a computer-readable storage medium and installed in the storage unit 52 of the control device 5 from the storage medium. Examples of computer-readable storage media include a hard disk (HD), a flexible disk (FD), a compact disk (CD), a magneto optical disk (MO), and a memory card. The control unit 51 may also be configured only with hardware without using the programs.

### <Operation of Substrate Processing System>

The substrate processing system 1 is configured as described above. Next, an example of substrate processing performed using the substrate processing system 1 configured as described above will be described.

First, a cassette C accommodating a plurality of wafers W is carried into the cassette station 2 of the substrate processing system 1 and placed on a cassette stage 21. Next, each wafer W in the cassette C is sequentially taken out by the transfer device 22 or the transfer device 23 and transferred to a transfer device 24 of the third block G3.

The wafer W transferred to the transfer device 24 of the third block G3 is supported by the transfer device 34 and transferred to a hydrophobic treatment apparatus provided in the second block G2, where hydrophobic treatment is performed. Subsequently, the wafer W is transferred by the transfer device 34 to the patterning film forming apparatus 31 serving as a resist film forming apparatus, where a resist film is formed on the wafer W, and thereafter transferred to a heat treatment apparatus, where the wafer W is prebaked. After the formation of the resist film or after the prebaking of the resist film, the control unit 51 may control, for example, the transfer device 34 and the transfer device 23 and transfer the wafer W to the measurement device 60, and measure, using the measurement device 60, the thickness of the resist film positioned on the surface of the wafer W. Thereafter, the wafer W is transferred by the transfer device 34 and the transfer device 23 to a transfer device of the fifth block G5. In addition, when a plurality of processing stations 3 are provided as illustrated in FIGS. 1 and 2, before being transferred to the transfer device of the fifth block G5, the wafer W is once placed on the transfer device of the fourth block G4 and then transferred to and from a plurality of transfer devices 34. Furthermore, as necessary, the wafer W may be transferred by the transfer device 34 to the peripheral exposure apparatus, where an exposure process may be performed on the peripheral portion of the wafer.

The wafer W transferred to the transfer device of the fifth block G5 is transferred by the transfer devices 41 and 42 to the exposure apparatus, where the wafer is subjected to an exposure process with a predetermined pattern. The wafer W may be cleaned by a cleaning apparatus before the exposure process.

The wafer W subjected to the exposure process is transferred by the transfer devices 41 and 42 to the transfer device of the fifth block G5. Thereafter, the wafer W is transferred by the transfer device 34 to the heat treatment apparatus and subjected to post-exposure baking.

The wafer W subjected to post-exposure bake is transferred by the transfer device 34 to a developing apparatus, where the wafer W is developed. After development is completed, the wafer W is transferred by the transfer device 34 to the heat treatment apparatus and subjected to post-bake.

Thereafter, the wafer W is transferred by the transfer device 34 to the transfer device 24 of the third block G3, and transferred by the transfer device 22 or the transfer device 23 of the cassette station 2 to a predetermined cassette C on the cassette stage 21. In this manner, a series of photolithography processes is completed.

It should be noted that the substrate processing system 1 in the present disclosure is not limited to the configuration and operation described above. For example, in the embodiment described above, the substrate processing system is directly connected to an exposure apparatus, and wafers W are transferred between the interface station 4 and the exposure apparatus. However, the substrate processing system 1 need not be directly connected to the exposure apparatus. In such a case, for example, after a wafer W is transferred from the cassette station 2 to the processing station 3 and subjected to necessary processing, the wafer W is transferred again to the cassette station 2 so as to be carried out of the system. In addition, among the processing apparatuses described above, those that are unnecessary may not be provided in the substrate processing system 1, or the processing by those apparatuses may not be performed.

Meanwhile, there is known a technique in which a wafer is transferred to a cassette chamber using a transfer device, the wafer is fixed to a fixing stage provided in the cassette chamber, and then the thickness of a film positioned on the surface of the wafer is measured by moving a film thickness meter above the wafer. In this technique, a moving mechanism for moving the film thickness meter above the wafer is provided in the cassette chamber. However, if a moving mechanism for the film thickness meter is additionally provided in the cassette chamber, the configuration of the substrate processing system may become complicated.

Therefore, in the substrate processing system 1 according to the present embodiment, an optical meter for measuring the thickness of a resist film positioned on the surface of a wafer W is provided in the housing of the measurement device 60, and the thickness of the resist film is measured using the optical meter while the wafer W is held by the transfer arm 23a of the transfer device 23. This may allow additionally providing a moving mechanism for moving the optical meter in the measurement device 60 to be omitted. Thus, according to the substrate processing system 1 of the present embodiment, the thickness of the resist film positioned on the surface of a wafer W may be measured with a simple configuration.

### <Configuration of Measurement Device>

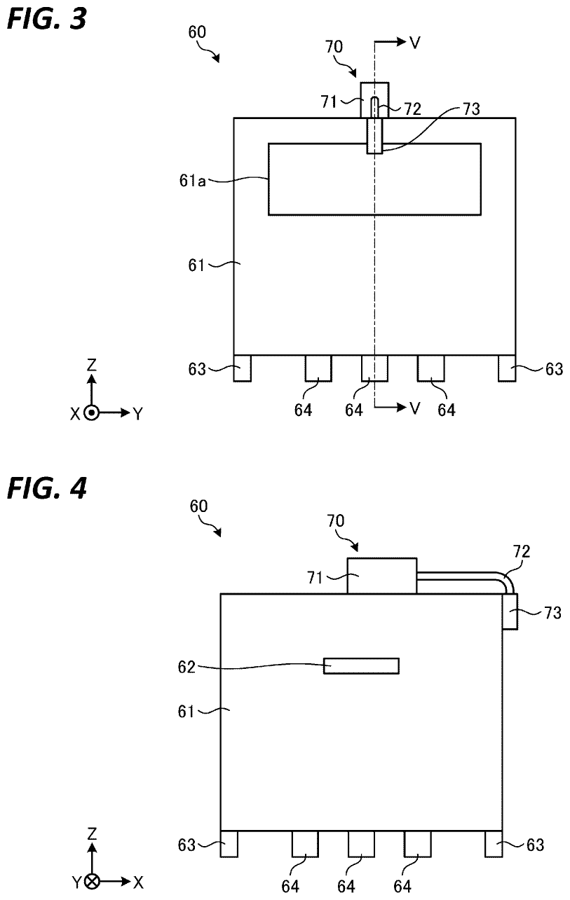

Next, the configuration of the measurement device 60 according to the present embodiment will be specifically described with reference to FIGS. 3 to 9.

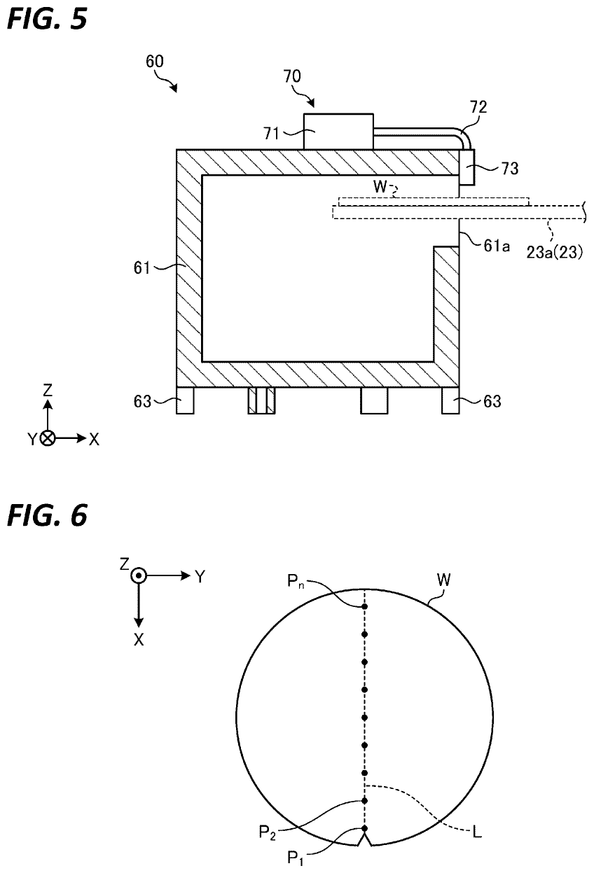

FIG. 3 is a schematic front view of the measurement device 60 according to the embodiment. FIG. 4 is a schematic side view of the measurement device 60 according to the embodiment. FIG. 5 is a partial cross-sectional view taken along line V-V of FIG. 3.

As illustrated in FIGS. 3 to 5, the measurement device 60 includes a housing 61 and an optical meter 70 (e.g., a film thickness meter). The housing 61 is a housing having an internal space capable of accommodating a wafer W in the same manner as a cassette C. The housing 61 has an opening 61a configured to allow a wafer W held by the transfer arm 23a to pass therethrough.

The optical meter 70 irradiates a wafer W with light and measures the thickness of a resist film based on reflected light from the wafer W. The optical meter 70 includes a spectroscopic unit 71, a waveguide unit 72, and a light incidence unit 73.

The spectroscopic unit 71 emits light toward the light incidence unit 73 via the waveguide unit 72, and spectroscopically analyzes reflected light that returns to the spectroscopic unit 71 via the light incidence unit 73 and the waveguide unit 72, so as to acquire spectroscopic spectrum data including light intensity for each wavelength.

The waveguide unit 72 guides light emitted from the spectroscopic unit 71 to the light incidence unit 73, and guides light incident on the light incidence unit 73 to the spectroscopic unit 71. The waveguide unit 72 is configured with, for example, an optical fiber and an optical coupler.

The light incidence unit 73 irradiates light guided by the waveguide unit 72 downward. The light incidence unit 73 also causes reflected light from the wafer W to enter the waveguide unit 72. The light incidence unit 73 is disposed at a position enabling the wafer W to be irradiated with light and reflected light from the wafer W to be received when the wafer W held by the transfer arm 23a passes through the opening 61a of the housing 61. The light incidence unit 73 is provided around the opening 61a of the housing 61. Specifically, the light incidence unit 73 is provided around the opening 61a of the housing 61 and above a passage path of the center of the wafer W that passes through the opening 61a of the housing 61. Accordingly, the optical meter 70 may acquire spectroscopic spectrum data for each of a plurality of measurement positions along a radial direction of the wafer W including the center of the wafer W. The spectroscopic spectrum data varies depending on the thickness of the resist film positioned on the surface of the wafer W. The optical meter 70 maintains a correspondence relationship between the thickness of the resist film and the spectroscopic spectrum data, and may measure the thickness of the resist film positioned on the surface of the wafer W using such a correspondence relationship and the spectroscopic spectrum data acquired by the spectroscopic unit 71.

As illustrated in FIG. 5, the control unit 51 (see, e.g., FIG. 1) controls the transfer device 23 to move the transfer arm 23a such that the wafer W held by the transfer arm 23a passes through the opening 61a of the housing 61, and measures the thickness of the resist film using the optical meter 70. That is, the control unit 51 moves the transfer arm 23a so that the wafer W gradually passes through the opening 61a of the housing 61 by repeatedly moving and stopping the transfer arm 23a at the opening 61a of the housing 61. For example, when a reference wafer and a measurement position of the optical meter 70 are previously aligned, the control unit 51 adjusts the position of the transfer arm by, for example, moving and stopping the transfer arm, so as to align the transfer arm with the measurement position of the optical meter 70. Here, the light incidence unit 73 of the optical meter 70 is provided around the opening 61a of the housing 61 and above the passage path of the center of the wafer W passing through the opening 61a of the housing 61. Therefore, as illustrated in FIG. 6, reflected light from the wafer W enters the light incidence unit 73 for each of multiple measurement positions P₁ to Pₙ along a straight-line L extending on the surface of the wafer W through the center of the wafer W and in a passing direction (e.g., the X-axis direction) of the wafer W with respect to the opening 61a of the housing 61. Accordingly, the optical meter 70 may acquire spectroscopic spectrum data for each of the multiple measurement positions P₁ to Pₙ. Then, the optical meter 70 may measure the thickness of the resist film positioned on the surface of the wafer W using the spectroscopic spectrum data for each of the multiple measurement positions P₁ to Pₙ. FIG. 6 is a view illustrating an example of measurement positions of a film thickness. The number n is a natural number and may be appropriately changed according to a measurement cycle of spectroscopic measurement by the spectroscopic unit 71 and a moving speed of the wafer W by the transfer arm 23a.

As described above, in the embodiment, the control unit 51 controls the transfer device 23 to move the transfer arm 23a such that the wafer W held by the transfer arm 23a passes through the opening 61a of the housing 61, and measures the thickness of the resist film using the optical meter 70. This may allow the thickness of the resist film to be measured with a simple configuration without moving the optical meter 70.

In addition, the control unit 51 measures, using the optical meter 70, the thickness of the resist film at each of multiple measurement positions P₁ to Pₙ along the straight-line L extending through the center of the wafer W on the surface of the wafer W and in the passing direction of the wafer W with respect to the opening 61a of the housing 61. This may allow the distribution of the thickness of the resist film to be easily measured.

Furthermore, in a case where the wafer W is transferred into the housing 61 from the opening 61a or transferred out of the housing 61 from the opening 61a, the control unit 51 may measure the thickness of the resist film using the optical meter 70 while holding the wafer W with the transfer arm 23a. This may allow the thickness of the resist film to be easily and efficiently measured.

Moreover, in the embodiment, the light incidence unit 73 of the optical meter 70 is provided around the opening 61a of the housing 61. This may allow the distribution of the thickness of the resist film of the wafer W passing through the opening 61a of the housing 61 to be easily measured.

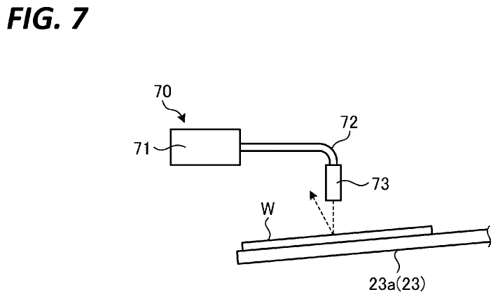

Meanwhile, the measurement result of the optical meter 70 may fluctuate due to inclination of the transfer arm 23a. FIG. 7 is a view illustrating variation in the measurement result of the optical meter 70 caused by inclination of the transfer arm 23a. As illustrated in FIG. 7, when the transfer arm 23a inclines with respect to the horizontal direction due to its own weight, the wafer W held by the transfer arm 23a also inclines, and therefore a portion of reflected light from the wafer W does not enter the light incidence unit 73 of the optical meter 70. When a portion of reflected light from the wafer W does not enter the light incidence unit 73 of the optical meter 70, the measurement result of the optical meter 70 deviates from the true measurement result, and the accuracy of film thickness measurement decreases.

Therefore, in the embodiment, the amount of variation in the measurement result of the optical meter 70 caused by inclination of the transfer arm 23a is measured, and the measurement result of the optical meter 70 is corrected based on the amount of variation.

Before performing measurement of the thickness of a resist film using the optical meter 70, the control unit 51 controls the transfer device 23 to move the transfer arm 23a such that a reference wafer (e.g., a reference substrate) held by the transfer arm 23a passes through the opening 61a of the housing 61. The reference wafer is a wafer W in which a resist film is not positioned on the surface. The reference wafer may be, for example, a silicon substrate. The control unit 51 irradiates the reference wafer with light using the optical meter 70, and acquires spectroscopic spectrum data for each of multiple measurement positions P₁ to Pₙ (see, e.g., FIG. 6) based on reflected light from the multiple measurement positions P₁ to Pₙ of the reference wafer. When the inclination of the wafer W held by the transfer arm 23a changes, the spectroscopic spectrum data of the reference wafer changes. That is, acquiring spectroscopic spectrum data of the reference wafer at each of the multiple measurement positions P₁ to Pₙ corresponds to measuring an amount of variation in the measurement result of the optical meter 70 caused by inclination of the transfer arm 23a. After performing measurement of the thickness of a resist film using the optical meter 70, the control unit 51 corrects the measurement result of the optical meter 70 for each of the multiple measurement positions P₁ to Pₙ based on the spectroscopic spectrum data of the reference wafer (the amount of variation in the measurement result of the optical meter 70). Specifically, the control unit 51 corrects the measurement result of the optical meter 70 by subtracting a value obtained by converting the spectroscopic spectrum data of the reference wafer into the thickness of a resist film from the thickness of the resist film measured by the optical meter 70.

As described above, by correcting the measurement result of the optical meter 70 based on the amount of variation in the measurement result of the optical meter 70 caused by inclination of the transfer arm 23a, the measurement accuracy of the thickness of the resist film may be improved.

In the embodiment, the measurement device 60 is disposed on the cassette stage 21 (see, e.g., FIGS. 1 and 2). As illustrated in FIGS. 3 and 4, the housing 61 of the measurement device 60 has handles 62 on outer surfaces facing each other across the opening 61a. By providing the housing 61 with the handles 62, the portability of the measurement device 60 may be improved when the measurement device 60 is disposed on the cassette stage 21 or removed from the cassette stage 21. In addition, by placing the measurement device 60 on the cassette stage 21 and connecting it to the control device 5 at startup or during maintenance of the substrate processing system 1, the film thickness may be easily measured. Furthermore, after the completion of startup or maintenance, the measurement device 60 may be easily detached from the cassette stage 21.

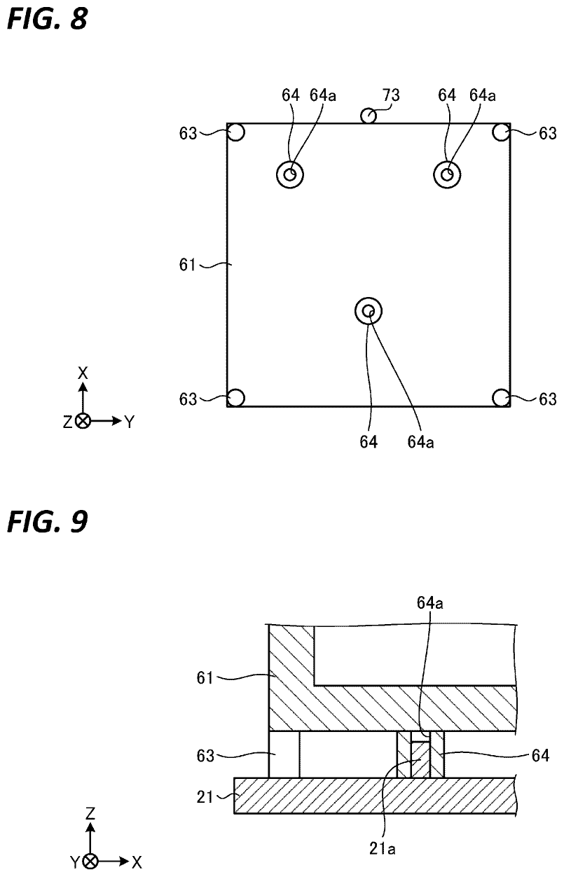

FIG. 8 is a schematic bottom view of the measurement device 60 according to the embodiment. FIG. 9 is a schematic view illustrating an example of a state in which the housing 61 of the measurement device 60 is placed on the cassette stage 21.

The housing 61 is configured to be placeable on the cassette stage 21. Specifically, as illustrated in FIGS. 8 and 9, the housing 61 has legs 63 on its bottom surface and is placed on the cassette stage 21 (see, e.g., FIGS. 1 and 2) via the legs 63. The legs 63 are provided, for example, at four corners of the bottom surface of the housing 61.

In addition, the cassette stage 21 is provided with protrusions 21a used for positioning the cassette C (see, e.g., FIGS. 1 and 2). The housing 61 has fitting portions 64 on its bottom surface that engage with the protrusions 21a of the cassette stage 21. The fitting portions 64 are protrusions formed by projecting portions of the bottom surface of the housing 61, and a plurality of the fitting portions 64 are provided in a region surrounded by the four legs 63 on the bottom surface of the housing 61. The fitting portions 64 have substantially the same height as the legs 63. The fitting portions 64 have fitting holes 64a that engage with the protrusions 21a of the cassette stage 21.

As illustrated in FIG. 9, in a state in which the housing 61 is placed on the cassette stage 21 via the legs 63, the protrusions 21a of the cassette stage 21 fit into the fitting holes 64a of the fitting portions 64, thereby suppressing positional displacement of the housing 61.

### <Measurement Process>

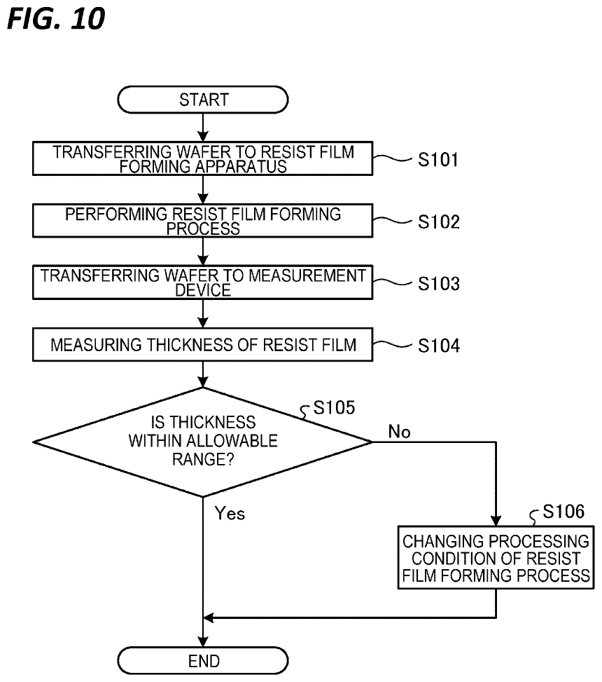

Next, the procedure of a measurement process according to the present embodiment will be described with reference to FIGS. 10 to 12. FIG. 10 is a flowchart illustrating an example of a procedure of a measurement process executed by the substrate processing system 1 according to the embodiment. The measurement process illustrated in FIG. 10 is executed at startup or during maintenance of the substrate processing system 1. In addition, the measurement process illustrated in FIG. 10 may also be executed during execution of substrate processing by the substrate processing system 1.

The control unit 51 controls, for example, the transfer devices 22, 23, and 34 to take out one wafer W from the cassette C and transfer the taken-out wafer W to the resist film forming apparatus (the patterning film forming apparatus 31) (step S101).

Next, the control unit 51 controls the resist film forming apparatus to perform a resist film forming process of forming a resist film on the wafer W (step S102). In the resist film forming process, while the wafer W is rotated at a predetermined rotational speed, a processing liquid for resist film formation is supplied onto the wafer W, thereby forming a resist film on the wafer W.

Thereafter, the control unit 51 controls, for example, the transfer devices 23 and 34 to take out the wafer W from the resist film forming apparatus and transfer the taken-out wafer W to the measurement device 60 (step S103).

Next, the control unit 51 controls the transfer device 23 to measure the thickness of the resist film using the optical meter 70 while holding the wafer W with the transfer arm 23a (step S104). That is, the control unit 51 measures the thickness of the resist film positioned on the surface of the wafer W for each of the plurality of measurement positions P₁ to Pₙ of the wafer W.

Next, the control unit 51 determines whether the thickness of the resist film measured by the optical meter 70 falls within a predetermined allowable range (step S105). That is, the control unit 51 determines whether the thickness of the resist film measured for each of the plurality of measurement positions P₁ to Pₙ of the wafer W falls within the allowable range.

When the thickness of the resist film measured by the optical meter 70 falls outside the allowable range (step S105, No), the control unit 51 changes processing conditions of the resist film forming process (step S106). For example, the control unit 51 changes, as the processing conditions of the resist film forming process, a rotational speed of the wafer W in the resist film forming apparatus or an amount of processing liquid supplied to the wafer W.

In the meantime, when the thickness of the resist film measured by the optical meter 70 falls within the allowable range (step S105, Yes), the control unit 51 terminates the measurement process without changing the processing conditions of the resist film forming process.

As described above, the control unit 51 may transfer the wafer W after the resist film forming process to the measurement device 60 and measure the thickness of the resist film using the optical meter 70 while holding the wafer W with the transfer arm 23a. This may allow the thickness of the resist film positioned on the surface of the wafer W after the resist film forming process to be easily measured.

In addition, when the thickness of the resist film measured by the optical meter 70 falls outside the allowable range, the control unit 51 may change the processing conditions of the resist film forming process. This may allow the processing conditions of the resist film forming process to be appropriately changed when the thickness of the resist film positioned on the surface of the wafer W after the resist film forming process falls outside the allowable range.

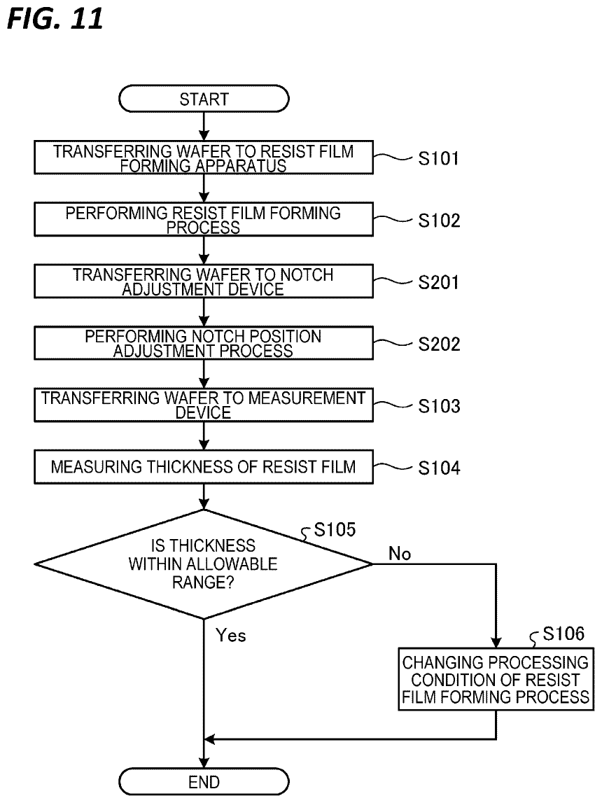

FIG. 11 is a flowchart illustrating another example of a procedure of a measurement process executed by the substrate processing system 1 according to the embodiment. The measurement process illustrated in FIG. 11 is executed at startup or during maintenance of the substrate processing system 1. In addition, the measurement process illustrated in FIG. 11 may also be executed during execution of substrate processing by the substrate processing system 1.

After executing the resist film forming process, the control unit 51 controls, for example, the transfer device 34 to take out the wafer W from the resist film forming apparatus and transfer the taken-out wafer W to the notch adjustment device 25 (step S201).

Next, the control unit 51 controls the notch adjustment device 25 to perform a notch position adjustment process of adjusting a notch position of the wafer W to a predetermined position (step S202).

Thereafter, the control unit 51 controls, for example, the transfer devices 23 and 34 to take out the wafer W from the notch adjustment device 25 and transfer the taken-out wafer W to the measurement device 60 (step S103). Subsequently, the control unit 51 executes the processes of steps S103 to S106.

As described above, the control unit 51 may transfer the wafer W, after the resist film forming process and after the notch position adjustment process, to the measurement device 60, and measure the thickness of the resist film using the optical meter 70 while holding the wafer W with the transfer arm 23a. This may allow the thickness of the resist film positioned on the surface of the wafer W after the resist film forming process and after the notch position adjustment process to be easily measured. In addition, by adjusting the notch position, the resist film thickness may be measured with the reference position aligned. Furthermore, measurement may be performed in the same orientation as the reference wafer, thereby preventing any deviation of the correction value.

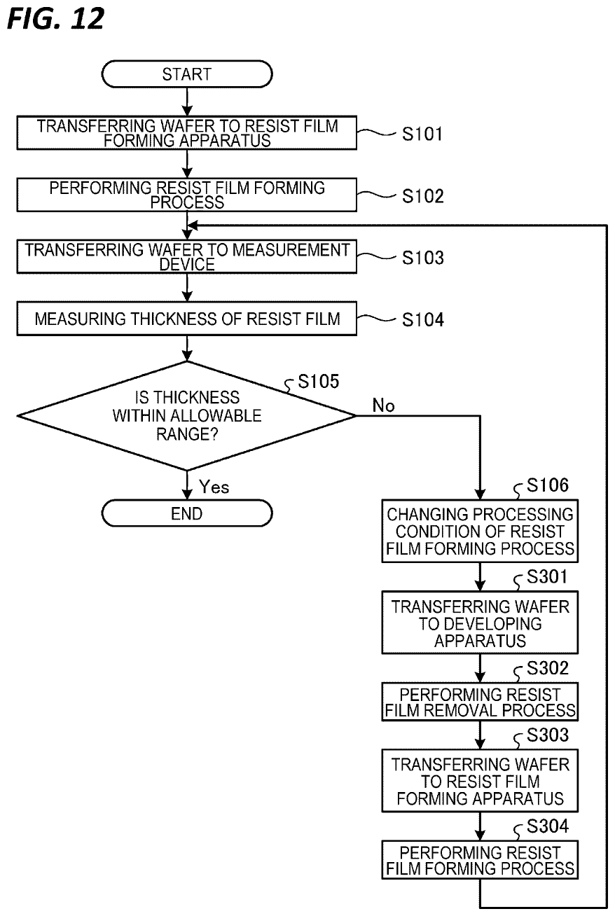

FIG. 12 is a flowchart illustrating another example of a procedure of a measurement process executed by the substrate processing system 1 according to the embodiment. The measurement process illustrated in FIG. 12 is executed at startup or during maintenance of the substrate processing system 1. In addition, the measurement process illustrated in FIG. 12 may also be executed during execution of substrate processing by the substrate processing system 1.

After changing the processing conditions of the resist film forming process, the control unit 51 controls, for example, the transfer devices 23 and 34 to take out a wafer W from the measurement device 60 and transfer the taken-out wafer W to the developing apparatus 32 (step S301).

Next, the control unit 51 controls the developing apparatus 32 to perform a resist film removal process of removing the resist film from the wafer W (step S302). In the resist film removal process, while the wafer W is rotated at a predetermined rotational speed, a processing liquid for removal is supplied onto the wafer W, thereby removing the entire resist film. The developing apparatus 32 is an example of a film removal apparatus.

Thereafter, the control unit 51 controls, for example, the transfer device 34 to take out the wafer W from the developing apparatus and transfer the taken-out wafer W to the resist film forming apparatus (the patterning film forming apparatus 31) (step S303).

Next, the control unit 51 controls the resist film forming apparatus under the processing conditions changed in step S106 to perform a resist film forming process of forming a resist film on the wafer W (step S304). Thereafter, the control unit 51 transfers the wafer W to the measurement device 60 and measures the thickness of the resist film again (step S105). When the thickness of the resist film falls outside the allowable range in step S105 (step S105, No), the processes of steps S301 to S304 and S103 to S105 are repeated until the thickness of the resist film falls within the allowable range.

As described above, after changing the processing conditions of the resist film forming process, the control unit 51 repeatedly executes the processes of steps S301 to S304 and S103 to S105 until the thickness of the resist film falls within the allowable range. This may allow the processing conditions of the resist film forming process to be appropriately changed when the thickness of the resist film positioned on the surface of the wafer W after the resist film forming process falls outside the allowable range.

### <Modification 1>

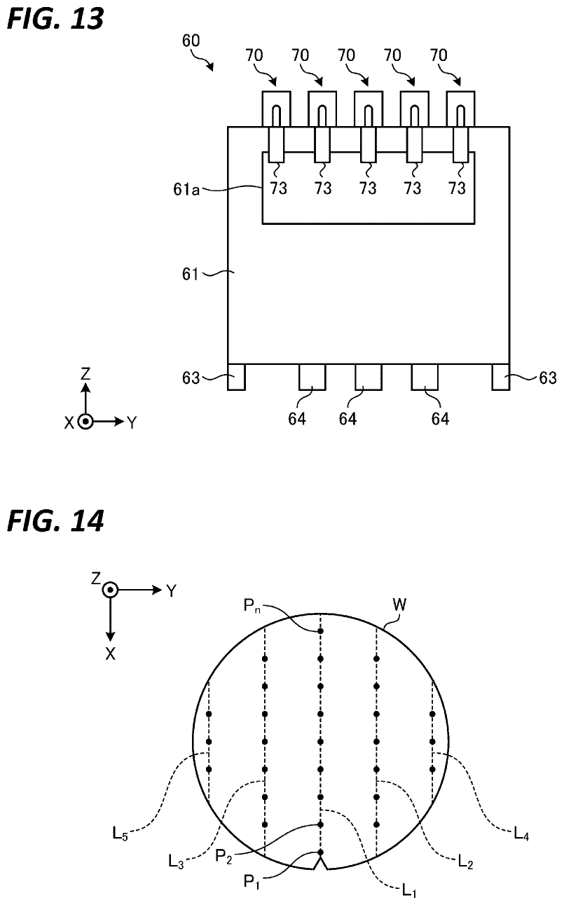

Next, various modifications of the embodiment will be described with reference to FIGS. 13 to 16. In the following modifications, the same reference numerals are assigned to portions identical to those of the embodiment, and redundant descriptions will be omitted.

FIG. 13 is a schematic front view of a measurement device 60 according to Modification 1 of the embodiment. FIG. 14 is a view illustrating an example of film thickness measurement positions. As illustrated in FIG. 13, in Modification 1, the measurement device 60 differs from the embodiment in that it includes a plurality of (e.g., five) optical meters 70. The plurality of optical meters 70 are arranged at intervals in a direction (e.g., the Y-axis direction) intersecting with the passing direction of a wafer W with respect to the opening 61a of the housing 61 (e.g., the X-axis direction). Here, the light incidence units 73 of the plurality of optical meters 70 are provided around the opening 61a of the housing 61 and above the passage path of the wafer W passing through the opening 61a of the housing 61. Therefore, as illustrated in FIG. 14, reflected light from the wafer W enters the light incidence units 73 for each of a plurality of measurement positions P1 to Pn arranged along a plurality of straight lines L₁ to L₅, which include a straight line L₁ extending through the center of the wafer W in the X-axis direction on the surface of the wafer W, and are arranged along the Y-axis direction.

Accordingly, the plurality of optical meters 70 may acquire spectroscopic spectrum data for each of the plurality of measurement positions P₁ to Pₙ arranged along the plurality of straight lines L₁ to L₅. Then, the plurality of optical meters 70 may measure the thickness of a resist film positioned on the surface of the wafer W using the spectroscopic spectrum data for each of the plurality of measurement positions P₁ to Pₙ arranged along the plurality of straight lines L₁ to L₅.

Thus, in Modification 1, the control unit 51 measures the thickness of the resist film for each of the plurality of measurement positions P₁ to Pₙ arranged along the plurality of straight lines L₁ to L₅ using the plurality of optical meters 70. This may allow the distribution of the thickness of the resist film to be easily and accurately measured.

### <Modification 2>

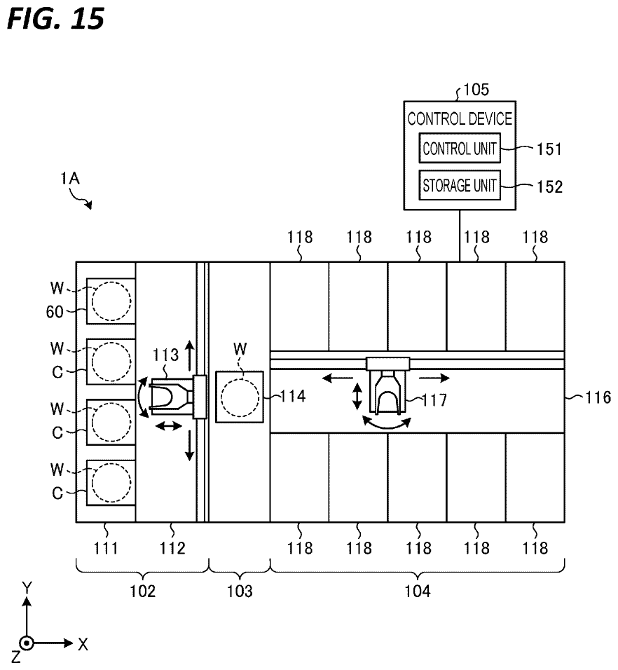

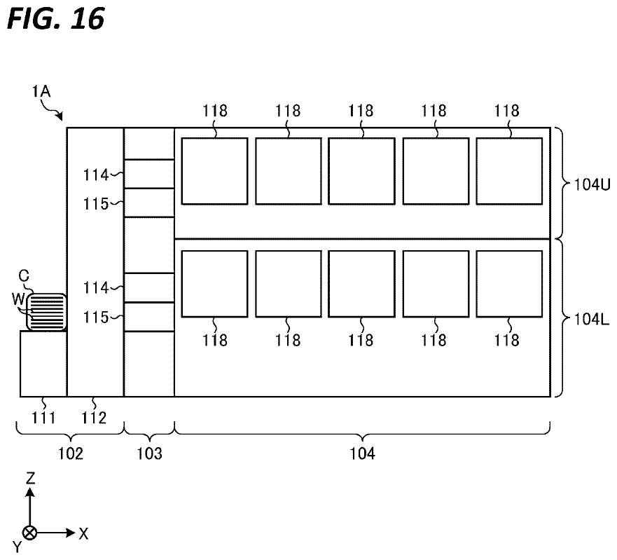

In the above embodiment, an example has been described in which the substrate processing system 1 is a photolithography processing system that performs a resist film forming process and a developing process on a wafer W. However, the substrate processing system may also be an etching processing system that performs an etching process on a film positioned on the surface of the wafer W. An example of this case will be described with reference to FIGS. 15 and 16.

FIG. 15 is a schematic plan view illustrating an outline of a configuration of a substrate processing system 1A according to Modification 2 of the embodiment. FIG. 16 is a schematic front view illustrating an outline of a configuration of the substrate processing system 1A according to Modification 2 of the embodiment.

As illustrated in FIG. 15, the substrate processing system 1A includes a loading/unloading station 102, a transfer station 103, and a processing station 104. These are arranged in order of the loading/unloading station 102, the transfer station 103, and the processing station 104.

The substrate processing system 1A transfers a wafer W loaded from the loading/unloading station 102 to the processing station 104 via the transfer station 103 and processes the wafer W in the processing station 104. In addition, the substrate processing system 1A returns the processed wafer W from the processing station 104 to the loading/unloading station 102 via the transfer station 103 and unloads it from the loading/unloading station 102 to the outside.

The loading/unloading station 102 includes a cassette stage 111 and a transfer section 112. A plurality of cassettes C, each accommodating a plurality of wafers W in a horizontal state, are placed on the cassette stage 111. In addition, a measurement device 60 is disposed on the cassette stage 111. The measurement device 60 measures the thickness of a film positioned on the surface of a wafer W.

The transfer section 112 is disposed between the cassette stage 111 and the transfer station 103 and includes a first transfer device 113 therein. The first transfer device 113 includes a wafer holder configured to hold one wafer W. The first transfer device 113 may move in a horizontal direction and a vertical direction and rotate about a vertical axis, and may transfer a wafer W between a cassette C or the measurement device 60 and the transfer station 103 using the wafer holder.

Next, the transfer station 103 will be described. As illustrated in FIGS. 15 and 16, a plurality of substrate stages 114 and a plurality of notch adjustment devices 115 are disposed inside the transfer station 103. Specifically, the processing station 104 described later includes an upper first processing station 104U and a lower second processing station 104L. The substrate stages 114 and the notch adjustment devices 115 are respectively disposed at positions corresponding to the first processing station 104U and the second processing station 104L.

Each notch adjustment device 115 includes a substrate rotation table on which a wafer W is placed and an optical sensor configured to optically detect a notch position of the wafer W. The notch adjustment device 115 performs a notch position adjustment process of rotating the wafer W using the substrate rotation table, detecting the notch position of the wafer W using the optical sensor, and adjusting the detected notch position to a predetermined position.

Next, the processing station 104 will be described. As illustrated in FIG. 16, the processing station 104 includes the first processing station 104U and the second processing station 104L. The first processing station 104U and the second processing station 104L are spatially partitioned by, for example, partitions and shutters and are arranged vertically.

The first processing station 104U and the second processing station 104L have similar configurations, and as illustrated in FIG. 15, each includes a transfer section 116, a second transfer device 117, and a plurality of etching processing units 118 (e.g., etching apparatuses).

The second transfer device 117 is disposed inside the transfer section 116 and transfers wafers W among the substrate stages 114, the notch adjustment devices 115, and the etching processing units 118.

The second transfer device 117 includes a wafer holder configured to hold one wafer W. The second transfer device 117 may move in a horizontal direction and a vertical direction and rotating about a vertical axis, and may transfer one wafer W using the wafer holder.

The plurality of etching processing units 118 are disposed on both sides of the transfer section 116. The number of etching processing units 118 included in the substrate processing system 1A is not limited to the illustrated example.

Each etching processing unit 118 performs a predetermined etching process on a wafer W. That is, the etching processing unit 118 performs an etching process of removing a film positioned on the surface of a wafer W by rotating the wafer W at a predetermined rotational speed and supplying an etching solution onto the wafer W.

As illustrated in FIG. 15, the substrate processing system 1A includes a control device 105. The control device 105 is, for example, a computer, and includes a control unit 151 and a storage unit 152. Programs for controlling various processes executed in the substrate processing system 1A are stored in the storage unit 152. The control unit 151 may be, for example, a CPU, or may be one or more circuits. The control unit 151 controls the operation of the substrate processing system 1A by reading out and executing the programs stored in the storage unit 152.

The programs may be recorded on a computer-readable storage medium and installed in the storage unit 152 of the control device 105 from the storage medium. Examples of the computer-readable storage media include a hard disk (HD), a flexible disk (FD), a compact disk (CD), a magneto-optical disk (MO), a memory card, a random-access memory (RAM), a read-only memory (ROM), a hard disk drive (HDD), a solid-state drive (SSD), or a combination thereof. The control unit 151 may also be configured only with hardware without using the programs.

In the substrate processing system 1A configured as described above, first, the first transfer device 113 of the loading/unloading station 102 takes out a wafer W from a cassette C placed on the cassette stage 111 and places the taken-out wafer W on a substrate stage 114. The wafer W placed on the substrate stage 114 is taken out from the substrate stage 114 by the second transfer device 117 of the processing station 104 and loaded into the etching processing unit 118.

Subsequently, the etching processing unit 118 performs an etching process on the wafer W that has been loaded. After the etching process on the wafer W, the control unit 151 may control, for example, the first transfer device 113, and the second transfer device 117 to transfer the wafer W to the measurement device 60 and measure, using the measurement device 60, the thickness of a film positioned on the surface of the wafer W. That is, the control unit 151 may transfer the etched wafer W to the measurement device 60 and measure the thickness of the film using the optical meter 70 while holding the wafer W with the transfer arm. In addition, after measurement of the film thickness by the measurement device 60, the control unit 151 may control the first transfer device 113 to transfer the wafer W to the notch adjustment device 115 and perform a notch position adjustment process on the wafer W using the notch adjustment device 115. Thereafter, the wafer W is unloaded from the measurement device 60 or the notch adjustment device 115 by the first transfer device 113 and placed on the substrate stage 114. Then, the processed wafer W placed on the substrate stage 114 is returned by the first transfer device 113 to a cassette C on the cassette stage 111.

As described above, in Modification 2, the control unit 151 may transfer the etched wafer W to the measurement device 60 and measure the thickness of the film using the optical meter 70 while holding the wafer W with the transfer arm 23a. Accordingly, also in the substrate processing system 1A according to Modification 2, the thickness of the film may be measured with a simple configuration.

### <Other Modifications>

In the above embodiment, an example has been described in which the measurement device 60 is disposed on, for example, the cassette stage 21, but the placement position of the measurement device 60 is not limited to the cassette stage 21. For example, the measurement device 60 may be disposed at a position accessible by each transfer device (e.g., the transfer devices 22, 23, 34, 41, and 42 in FIG. 1 or FIG. 2) in the cassette station 2, the processing station 3, or the interface station 4.

In the above embodiment, an example has been described in which the substrate processing system 1 is a photolithography processing system that performs a resist film forming process and a developing process on a wafer W, but the substrate processing system is not limited to a photolithography processing system. For example, the substrate processing system may be applied to apparatuses that require film thickness measurement, such as a film forming apparatus or a substrate bonding apparatus.

As described above, a substrate processing apparatus (e.g., the substrate processing systems 1 and 1A) according to the embodiment includes a transfer device (e.g., the transfer device 23 or the first transfer device 113), a measurement device (e.g., the measurement device 60), and a control unit (e.g., the control units 51 and 151). The transfer device includes a transfer arm (e.g., the transfer arm 23a) configured to hold and transfer a substrate (e.g., a wafer W). The measurement device measures the thickness of a film (e.g., a resist film) positioned on a surface of a substrate. The measurement device includes a housing (e.g., the housing 61) having an opening (e.g., the opening 61a) configured to allow a substrate held by the transfer arm to pass therethrough, and a film thickness meter (e.g., the optical meter 70) provided in the housing to measure the thickness of a film of the substrate. The control unit controls the transfer device to move the transfer arm such that the substrate passes through the opening of the housing while being held by the transfer arm, and measures the thickness of the film using the film thickness meter. Accordingly, the thickness of a film positioned on the surface of the substrate may be measured with a simple configuration.

According to the present disclosure, the thickness of a film positioned on a surface of a substrate may be measured using a simple configuration.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a transfer device including a transfer arm configured to hold and transfer a substrate;
a measurement device configured to measure a thickness of a film positioned on a surface of the substrate; and
a controller,
wherein the measurement device includes:
a housing having an opening configured to allow the substrate held by the transfer arm to pass therethrough, and
a film thickness meter provided in the housing and configured to measure the thickness of the film of the substrate,
wherein the controller is configured to:
control the transfer device to move the transfer arm such that the substrate held by the transfer arm passes through the opening of the housing, and
measure the thickness of the film using the film thickness meter.

2. The substrate processing apparatus according to claim 1, wherein the film thickness meter is an optical meter configured to irradiate the substrate with light and measure the thickness of the film based on reflected light from the substrate.

3. The substrate processing apparatus according to claim 2, wherein the optical meter includes a light incidence portion configured to receive reflected light from the substrate, and
the light incidence portion is provided around the opening of the housing.

4. The substrate processing apparatus according to claim 1, further comprising:
a cassette stage configured to place thereon a cassette accommodating the substrate,
wherein the measurement device is disposed on the cassette stage.

5. The substrate processing apparatus according to claim 4, wherein the housing is configured to be placed on the cassette stage.

6. The substrate processing apparatus according to claim 4, wherein the cassette stage includes a protrusion used for positioning the cassette, and
the housing includes a fitting portion configured to engage with the protrusion on a bottom surface thereof.

7. The substrate processing apparatus according to claim 1, wherein the housing includes a handle on outer surfaces facing each other across the opening.

8. The substrate processing apparatus according to claim 2, wherein the controller is configured to:
measure, using the optical meter, the thickness of the film for each of a plurality of measurement positions arranged along a straight line that passes through a center of the substrate on a surface of the substrate and extends in a passing direction of the substrate with respect to the opening of the housing.

9. The substrate processing apparatus according to claim 8, wherein the controller is configured to:
before performing measurement of the thickness of the film using the optical meter, control the transfer device to move the transfer arm such that a reference substrate, held by the transfer arm and having no film positioned on a surface thereof, passes through the opening of the housing;
irradiate the reference substrate with light using the optical meter, and measure, based on reflected light from the plurality of measurement positions of the reference substrate, an amount of variation in a measurement result by the optical meter caused by inclination of the transfer arm; and
after performing measurement of the thickness of the film using the optical meter, correct the measurement result obtained by the optical meter for each of the plurality of measurement positions based on the amount of variation.

10. The substrate processing apparatus according to claim 8, wherein the measurement device includes a plurality of optical meters arranged at intervals in a direction intersecting with a passing direction of the substrate with respect to the opening of the housing, and
wherein the controller is configured to:
measure, using the plurality of optical meters, the thickness of the film for each of a plurality of measurement positions arranged along a plurality of straight lines, which include a straight line extending through a center of the substrate on a surface of the substrate in the passing direction of the substrate with respect to the opening of the housing and are arranged in the intersecting direction.

11. The substrate processing apparatus according to claim 1, wherein the controller is configured to:
measure, using the film thickness meter, the thickness of the film while holding the substrate with the transfer arm when the substrate is loaded into the housing through the opening or when the substrate is unloaded from the housing through the opening.

12. The substrate processing apparatus according to claim 1, further comprising:
a film forming apparatus configured to perform a film forming process on the substrate,
wherein the controller is configured to:
control the transfer device to transfer the substrate after the film forming process to the measurement device, and
measure, using the film thickness meter, the thickness of the film while the substrate is held by the transfer arm.

13. The substrate processing apparatus according to claim 12, further comprising:
an adjustment device configured to perform a notch position adjustment process of adjusting a notch position of the substrate after the film forming process,
wherein the controller is configured to:
control the transfer device to transfer the substrate after the film forming process and after the notch position adjustment process to the measurement device, and
measure, using the film thickness meter, the thickness of the film while holding the substrate with the transfer arm.

14. The substrate processing apparatus according to claim 12, wherein the controller is configured to:
change processing conditions of the film forming process when the thickness of the film measured by the film thickness meter falls outside an allowable range.

15. The substrate processing apparatus according to claim 14, further comprising:
a film removal apparatus configured to perform a film removal process of removing the film from the substrate,
wherein the controller is configured to:
after changing the processing conditions of the film forming process, control the transfer device and another transfer device to transfer the substrate from the measurement device to the film removal apparatus;
control the another transfer device to transfer the substrate after the film removal process from the film removal apparatus to the film forming apparatus;
control the transfer device and the another transfer device to transfer the substrate after the film forming process from the film forming apparatus to the measurement device, and measure, using the film thickness meter, the thickness of the film while holding the substrate with the transfer arm; and
repeatedly execute the process until the thickness of the film falls within the allowable range.

16. The substrate processing apparatus according to claim 1, further comprising:
an etching apparatus configured to perform an etching process of etching the film positioned on a surface of the substrate,
wherein the controller is configured to:
transfer the substrate after the etching process to the measurement device; and measure, using the film thickness meter, the thickness of the film while holding the substrate with the transfer arm.

17. A method of measuring a thickness of a film positioned on a surface of a substrate, the method comprising:
providing a substrate processing apparatus that includes
a transfer device including a transfer arm configured to hold and transfer the substrate, and
a measurement device configured to measure the thickness of the film positioned on a surface of the substrate,
wherein the measurement device includes, a housing having an opening configured to allow the substrate held by the transfer arm to pass therethrough, and a film thickness meter provided in the housing and configured to measure the thickness of the film of the substrate;
controlling the transfer apparatus to transfer the substrate held by the transfer arm to the measurement device; and
measuring, using the film thickness meter, the thickness of the film while holding the substrate with the transfer arm.

18. The method according to claim 17, wherein the film thickness meter is an optical meter configured to irradiate the substrate with light and measure the thickness of the film based on reflected light from the substrate.
